(19) United States
(12) Patent Application Publication
(10) Pub. No.: US 2016/0374198 A1
(43) Pub. Date: Dec. 22, 2016

(54) PRINTED CIRCUIT BOARD

(71) Applicant: Samsung Electro-Mechanics Co., Ltd., Suwon-si (KR)

(72) Inventors: Heung-Kyu KIM, Cheongju-si (KR); Suk-Hyeon CHO, Suwon-si (KR); Chil-Woo KWON, Ansan-si (KR); Yul-Kyo CHUNG, Yongin-si (KR); Going-Sik KIM, Suwon-si (KR)

(73) Assignee: Samsung Electro-Mechanics Co., Ltd., Suwon-si (KR)

(21) Appl. No.: 15/002,428

(22) Filed: Jan. 21, 2016

(30) Foreign Application Priority Data
Jun. 18, 2015 (KR) 10-2015-0086415

(51) Int. Cl. H05K 1/03

(52) U.S. Cl. CPC H05K 1/0306; H05K 1/032; H05K 2201/068; H05K 2201/09854

(57) ABSTRACT

A printed circuit board includes a core layer including a glass core, a first resin layer disposed on a first surface of the glass core, and a second resin layer formed on a second surface of the glass core; build-up layers disposed on the first and second surfaces of the core layer; and a conductive pattern formed in multiple layers on the build-up layers, wherein the core layer has asymmetric coefficients of thermal expansion opposing sides thereof with respect to a center of the glass core in a thickness direction.

CROSS-REFERENCE TO RELATED APPLICATION(S)

This application claims the benefit under 35 USC 119(a) of Korean Patent Application No. 10-2015-0086415 filed on Jun. 18, 2015, in the Korean Intellectual Property Office, the entire disclosure of which is incorporated herein by reference for all purposes.

### BACKGROUND

1. Field

The following description relates to a printed circuit board.

2. Description of Related Art

As thin printed circuit boards (PCBs) have become thinner and thinner, the utilization of thin PCBs is severely limited by warpage and reliability issues. A glass core structure in which a glass plate is embedded in a core layer of the printed circuit board has been developed to resolve those problems.

For instance, KR Patent Publication No. 2012-0095426 describes an example of a glass core substrate for an integrated circuit (IC) device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a printed circuit board includes: a core layer including a glass core, a first resin layer disposed on a first surface of the glass core, and a second resin layer formed on a second surface of the glass core; build-up layers disposed on opposing surfaces of the core layer; and a conductive pattern formed in multiple layers on the build-up layers, wherein the core layer includes asymmetric coefficients of thermal expansion on opposing sides thereof with respect to a center of the glass core in a thickness direction.

A volume of the first resin layer may be greater than a volume of the second resin layer.

The printed circuit board may further include a trench disposed on the first surface of the glass core and filled by the first resin layer.

The trench may be formed in a straight line in x-axis and y-axis directions.

The printed circuit board may further include a groove disposed on the first surface of the glass core and filled by the first resin layer.

The groove may be formed in at least one shape selected from the group consisting of round, oval and square.

The first and second resin layers may include a reinforcing agent.

The printed circuit board may further include: a through-hole passing through the core layer; and a resin protecting unit disposed between the glass core and the through hole.

The through-hole may have an hourglass shape.

According to another general aspect, a printed circuit board includes: a core layer including a glass core, a first resin layer disposed on a first surface of the glass core, and a second resin layer formed on a second surface of the glass core; build-up layers disposed on opposing surfaces of the core layer; and a conductive pattern formed in multiple layers on the build-up layers, wherein the first resin layer forms an electronic component mounting surface of which an electronic component mounting pad on which an electronic component is mounted is exposed, the second resin layer forms an external connection terminal contacting surface of which an external connection terminal pad is exposed, and a volume of the first resin layer is greater than a volume of the second resin layer.

The printed circuit board may further include a trench disposed on the first surface of the glass core and filled by the first resin layer.

The printed circuit board may further include a groove formed on the first surface of the glass core and filled by the first resin layer.

A coefficient of thermal expansion of the electronic component mounting surface may be greater than a coefficient of thermal expansion of the external connection terminal contacting surface with respect on a thickness direction.

The resin layer may include a reinforcing agent.

The printed circuit board of claim 10, may further include: a through-hole passing through the core layer; and a resin protecting unit disposed between the glass core and the through hole.

The through-hole may have an hourglass shape.

Other features and aspects will be apparent from the following detailed description, the drawings, and the claims.

### BRIEF DESCRIPTION OF THE DRAWINGS

FIG. 1 is a sectional view illustrating a general printed circuit board structure.

FIG. 2 is a sectional view illustrating an example of a printed circuit board structure having improved warpage resistance.

FIGS. 3A-3D are plan views illustrating examples of a glass core on which trenches are formed.

FIGS. 4A and 4B are plan views illustrating examples of a glass core on which grooves are formed.

FIG. 5 is a sectional view illustrating an example of a core layer involving a glass core.

FIG. 6 and FIG. 7 are sectional views illustrating other examples of printed circuit board structures having improved warpage resistance.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

### Printed Circuit Board

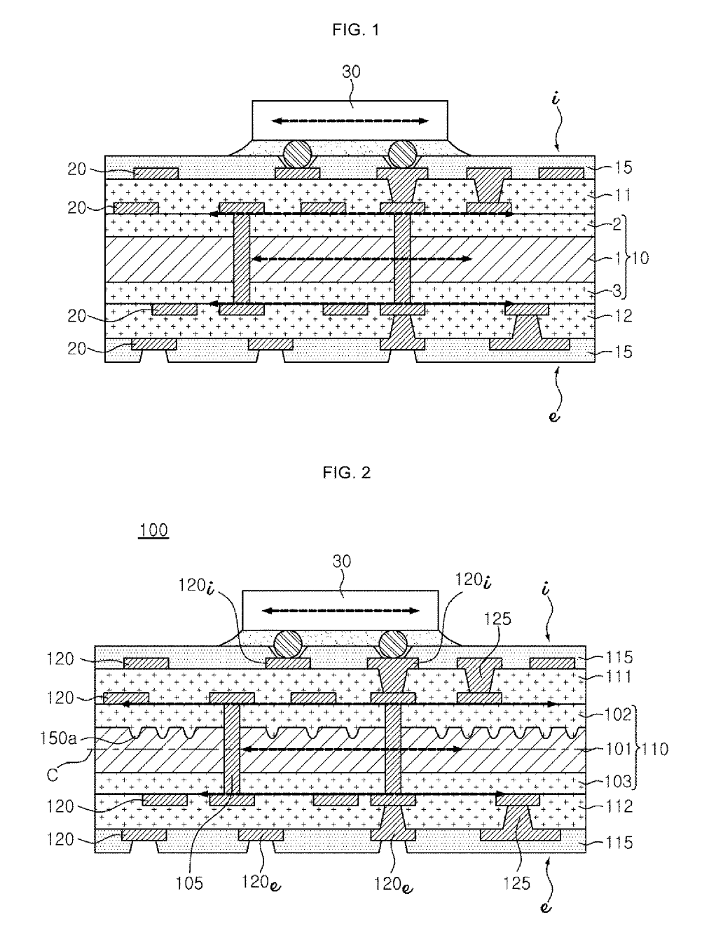

FIG. 1 is a sectional view illustrating a general printed circuit board structure.

Referring to FIG. 1, a general printed circuit board includes a glass core 1 and resin layers 2, 3 on opposing surfaces (e.g., top and bottom surfaces) of the glass core 1 in a core layer 10. Build-up layers 11, 12 are further formed on both surfaces of the core layer 10, and conductive patterns 20 are formed on the core layer 10 and the build-up layers 11, 12 in multiple layers. A solder resist 15 is further formed to expose an electronic component (e.g., a semiconductor chip) mounting pad and an external connection terminal pad among the conductive patterns formed on the build-up layers 11, 12. A solder bump is formed on the exposed electronic component mounting pad and an electronic component (e.g., semiconductor chip) 30 is mounted on the solder bump.

When the semiconductor chip 30 is mounted on the printed circuit board for semiconductor packages, warpage may be caused due to different coefficients of thermal expansion (CTEs) at a high temperature which is required to mount the semiconductor chip 30. As shown in FIG. 1, when the glass core 1 having a high a rigidity and a low coefficient of thermal expansion is formed in the core layer 10, the warpage occurrence may be reduced at a high temperature during manufacturing the printed circuit board.

However, since the printed circuit board, on which the semiconductor chip 30 is mounted, has asymmetric coefficients of thermal expansion between the materials of the upper and the lower surface due to the semiconductor chip 30, it is difficult to completely prevent the occurrence of warpage. That is, the printed circuit board is initially formed symmetrically, but becomes asymmetric in CTEs due to the mounting of the semiconductor chip 30.

Thus, when reflowing, which is accompanied by rising and falling of temperature, is performed to mount the semiconductor chip 30, it is difficult to completely prevent the occurrence of warpage due to different CTEs.

In a printed circuit board according to an example disclosed herein, the above described occurrence of warpage at a high temperature is resolved, even when the semiconductor chip is mounted, by forming asymmetrical CTEs for each side (e.g., top and bottom) of the printed circuit board with respect to the center of the core layer in a thickness direction.

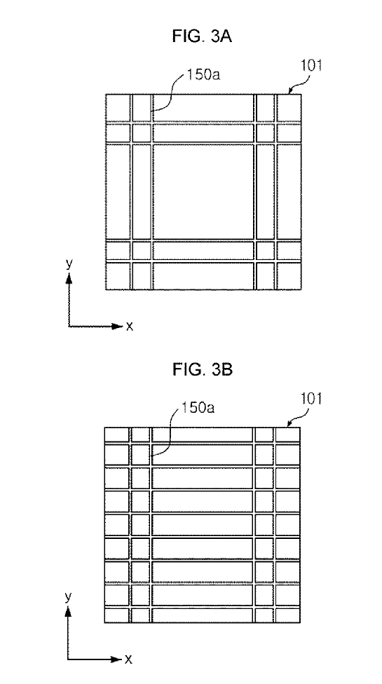

FIG. 2 is a sectional view illustrating an example of a printed circuit board structure having high warpage resistance.

Referring to FIG. 2, a printed circuit board 100, according to an example, includes a core layer 110 including a glass core 101 and build-up layers 111, 112 formed on both surfaces of the core layer 110. Conductive patterns 120 are formed in multiple layers on the core layer 110 and the build-up layers 111, 112. The conductive patterns 120 in different layers may be connected with each other through a through-hole 105 passing through the core layer 110 and a via 125 passing through the build-up layers 111, 112.

The core layer 110 includes a glass core 101 and resin layers 102, 103 respectively formed on one surface (e.g., a top surface) and another, opposing surface (e.g., a bottom surface) of the glass core 101. CTEs of each side may be formed asymmetrically with respect to the center C of the core layer 110 in a thickness direction. The glass core 101 may include, for example, pure silicon dioxide (about 100% SiO2), soda-lime glass, borosilicate glass, alumino-silicate glass or the like. The glass core 101 is not, however, limited to these materials. The glass core 101 may also include, for example, fluoride glass, phosphate glass, chalcogenide glass or the like. The glass core 101 may further include other additives to improve physical properties of the glass. Examples of the additive may include calcium carbonate (for example, lime) and sodium carbonate (for example, soda), magnesium, calcium, manganese, aluminum, lead, boron, iron, chromium, potassium, sulfur, antimony, carbonate and/or oxide thereof or carbonate and/or oxide of other atoms.

The resin layers 102, 103 and the build-up layers 111, 112 may include a thermosetting resin such as an epoxy resin, a thermoplastic resin such as a polyimide or the like. The resin layers 102, 103 and the build-up layers 111, 112 may further include a reinforcing agent. The reinforcing agent may be, for example, a fabric reinforcing agent, an inorganic filler or the like. The fabric reinforcing agent may be a glass fiber or may be formed in a prepreg by immersing glass fiber in the resin.

The conductive pattern 120 may be formed of any kind of conductive metal, for example, Cu. The through-hole 105 and the via 125 may be formed of the same material as the conductive pattern 120, for example, Cu. However, the material of the through-hole 105 and the via 125 is not limited thereto.

In an example, volume of the resin layer 102 formed on one surface (e.g., top surface) i of the glass core 101 is greater than that of the resin layer 103 formed on the other, opposite surface (e.g., bottom surface) e of the glass core 101. Thus, coefficients of thermal expansion (CTE) of each side are asymmetric based on the center C in a thickness direction of the core layer 110.

The printed circuit board 100 may be a printed circuit board for semiconductor package, and the one surface i of the printed circuit board 100 is an electronic component mounting surface on which an electronic component mounting pad 120i where an electronic component (e.g., semiconductor chip 30) is to be mounted is exposed, and the other surface e of the printed circuit board 100 is an external connection terminal contacting surface on which an external connection terminal pad 120e is exposed. A solder resist 115 is formed to expose the electronic component mounting pad 120i and the external connection terminal pad 120e among the conductive patterns formed on the build-up layers 111, 112.

The volume of the resin layer 102 formed on the electronic component mounting surface i is formed to be greater than that of the resin layer 103 formed on the external connection terminal contacting surface e so that when a semiconductor chip 30 is mounted, the problem of having asymmetric CTEs is solved. That is, by forming the volume of the resin layer 102 to be greater than the volume of the resin layer 103, and thereby forming the resin layer 102 to have a higher CTE than that of the resin layer 103, the CTEs of the top and bottom sides of the printed circuit board 100 become symmetric when the semiconductor chip 30 is mounted on the resin layer 200.

Accordingly, the warpage caused due to different CTEs may be effectively avoided during the reflowing including rising and falling temperature to mount the semiconductor chip 30.

A trench 150a is formed on one surface (e.g., the top surface) of the glass core 101, which us on the same side, with respect to the center C, as the one surface i of the printed circuit board 100. The trench 150a is filled by the resin layer 102 formed on the one surface of the glass core 101. Accordingly, the volume of the resin layer 102 formed on one surface of the glass core 101 becomes greater than that of the resin layer 103 formed on the other, opposite surface (e.g., the bottom surface) of the glass core 101. The one surface of the glass core 101 on which the trench 150a is formed is an electronic component mounting surface.

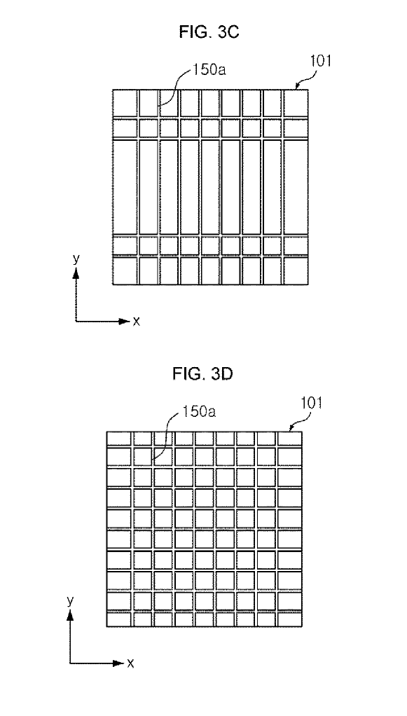

FIGS. 3A to 3D are plan views illustrating examples of a glass core on which trenches 150a are formed.

Referring to FIG. 3A to FIG. 3D, trenches 150a of various shapes are formed on the glass core 101. As shown in FIG. 3A to FIG. 3D, the trench 150a may be formed in a straight line in the x-axis and the y-axis directions on the one surface of the glass core 101. However, the trench 150a is not limited to this configuration. For example, the trench 150a may include any elongated shaped groove formed on the glass core 101.

The volume of the resin layer 102 is controlled by utilizing shape, width, density or the like of the trench 150a. Further, the CTE of both the top and bottom surfaces of the core layer 110 may be controlled.

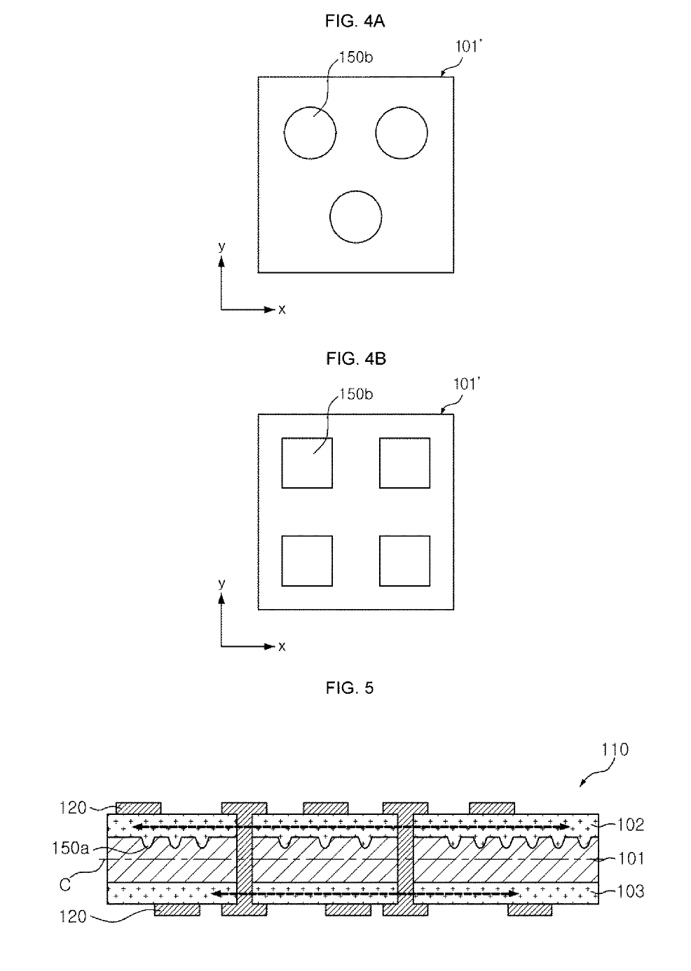

FIGS. 4A and 4B are plan views illustrating examples of a glass core 101′ on which grooves 150b are formed.

Referring to FIG. 4A and FIG. 4B, various shapes of grooves 150b are formed on the glass core 101′. As shown in FIG. 4A and FIG. 4B, the groove 150b is formed on one surface of the glass core 101′. The groove 150b is filled by the resin layer 102 formed on the one surface of the glass core 101′. Accordingly, the volume of the resin layer 102 formed on the one surface of the glass core 101′ becomes greater than that of the resin layer 103 formed on the other, opposite surface of the glass core 101′. The one surface of the glass core 101′ on which the groove 150b is formed is an electronic component mounting surface.

The groove 150b may be formed in at least one of a round, oval and square shape on the one surface of the glass core 101′. However, the trench 150b is not limited these shapes. For example, the groove 150b may be any groove formed in a particular shape on the one surface of the glass core 101′.

The volume of the resin layer 102 is controlled by utilizing shape, width, density or the like of the groove 150b. Further, the CTE of both the top and bottom surfaces of the core layer 110 may be controlled.

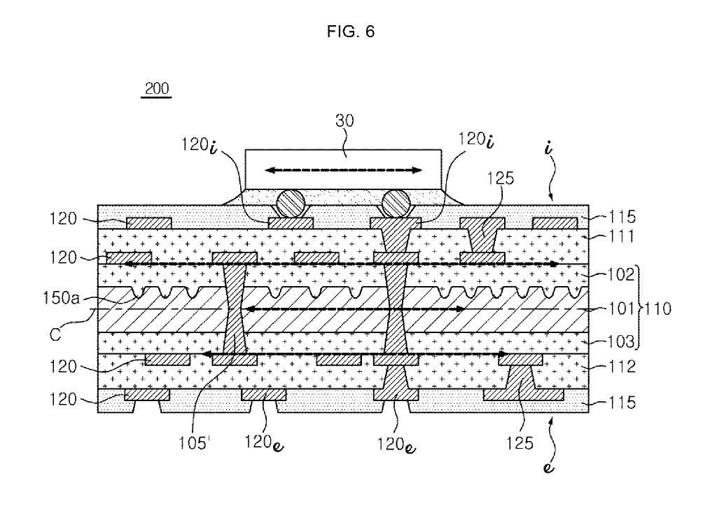

FIG. 5 is a sectional view illustrating an example of a core layer including a glass core.

Referring to FIG. 5, the core layer 110 is formed by laminating the resin layers 102, 103 on the one surface and the other surface, respectively, of the glass core 101. The trench 150a is formed on the one surface of the glass core 101 and is filled by the resin layer 102 formed on the one surface of the glass core 101. Thus, the volume of the resin layer 102 is greater than that of the resin layer 103. When the volume of the resin layer 102 is greater than the volume of the resin layer 103, the core layer 110 may have different CTEs on each side thereof with respect to the center C in the thickness direction of the glass core 101.

The one surface of the glass core 101, in which the volume of the resin layer 102 is increased by forming the trench 150a, is an electronic component mounting surface on which an electronic component (e.g., the semiconductor chip 30) is mounted. The build-up layers 111, 112 may be further formed on both surfaces of the core layer 110 in which CTEs are formed asymmetrically.

In FIG. 2, only one build-up layer is formed on the upper surface and the lower surface of the core layer 110. However, the printed circuit board 100 is not limited to such a configuration. For example, two or more build-up layers may be formed on both surfaces of the core layer 110.

Since the build-up layer is usually symmetrically formed on both surfaces of the core layer, the printed circuit board 100 including the build-up layers 111, 112 formed on both surfaces of the core layer 110 in which CTEs are formed asymmetrically may have a higher CTE on the electronic component mounting surface i than the CTE on the external connection terminal contacting surface e based on the center C in the thickness direction. That is, when the semiconductor chip 30 is mounted on the electronic component mounting surface i by forming the resin layer 102 with a higher CTE than the resin layer 103 to have greater volume than the resin layer 103, the CTE of each side of the printed circuit boad 100 may become symmetric.

Thus, when reflowing is performed for mounting the semiconductor chip 30 accompanying rising and falling of temperature, the occurrence of warpage due to different CTEs may be effectively eliminated.

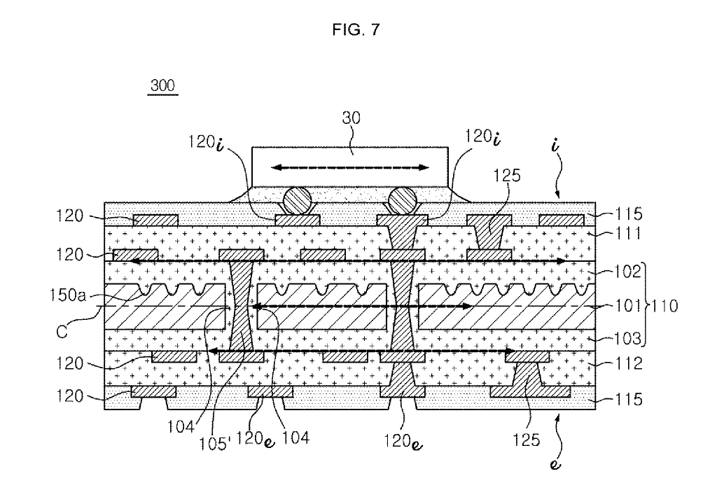

FIG. 6 and FIG. 7 are sectional views illustrating other examples of printed circuit board structures.

Referring to FIG. 6, according to another example, a printed circuit board 200 includes a through-hole 105′ formed in an hourglass shape with a decreasing cross-sectional dimension toward the center C and passing through the core layer 110 to connect the conductive patterns 120 of different layers. All constitutions of the printed circuit board 100 described above may be applied to the printed circuit board 200, except the constitution of the hourglass shaped through-hole 105′.

Referring to FIG. 7, according to still another example, a printed circuit board 300 includes a resin protecting unit 104 formed between the through-hole 105′ and the glass core 101. When the through-hole 105′ is formed inside the glass core 101, adhesion between the glass core 101 and the through hole 105′ may be deteriorated. As shown in FIG. 7, the resin protecting unit 104 is formed to eliminate a gap between the glass core 101 and the through hole 105′ and thus improve the adhesion between the glass core 101 and the through hole 105′. In addition, when the through-hole 105′ is formed inside the glass core 101, the resin protecting unit 104 may prevent the generation of cracks in the glass core 101 during the processing of holes with a laser.

All constitutions of the printed circuit board 200 described above may be applied to the printed circuit board 300, except the constitution of the resin protecting unit 104 formed between the glass core 101 and the through hole 105′.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

### DESCRIPTION OF REFERENCE NUMERALS

100, 200, 300; Printed circuit board

101, 101′: Glass core

2, 3, 102, 103: Resin layer

10, 110: Core layer

11, 12, 111, 112: Build-up layer

20, 120: Conductive pattern

15, 115: Solder resist

30: Semiconductor chip

105: Through-hole

125: Via

120 i: Electronic component mounting pad

120 e: External connection terminal pad

150a: Trench

150b: Groove

1. A printed circuit board comprising:
a core layer comprising a glass core, a first resin layer disposed on a first surface of the glass core, and a second resin layer formed on a second surface of the glass core, the glass core being a glass plate;
build-up layers disposed on opposing surfaces of the core layer; and
a conductive pattern formed in multiple layers on the core layer and the build-up layers,
wherein the core layer comprises asymmetric coefficients of thermal expansion on opposing sides of the core layer with respect to a center of the glass core in a thickness direction.

2. The printed circuit board of claim 1, wherein a volume of the first resin layer is greater than a volume of the second resin layer.

3. The printed circuit board of claim 1, further comprising a trench disposed on the first surface of the glass core and filled by the first resin layer.

4. The printed circuit board of claim 3, wherein the trench is formed in a straight line in x-axis and y-axis directions.

5. The printed circuit board of claim 1, further comprising a groove disposed on the first surface of the glass core and filled by the first resin layer.

6. The printed circuit board of claim 5, wherein the groove is formed in at least one shape selected from the group consisting of round, oval and square.

7. The printed circuit board of claim 1, wherein the first and second resin layers comprise a reinforcing agent.

8. The printed circuit board of claim 1, further comprising:
a through-hole passing through the core layer; and
a resin protecting unit disposed between the glass core and the through hole.

9. The printed circuit board of claim 8, wherein the through-hole comprises an hourglass shape.

10. A printed circuit board comprising:
a core layer comprising a glass core, a first resin layer disposed on a first surface of the glass core, and a second resin layer formed on a second surface of the glass core, the glass core being a glass plate;
build-up layers disposed on opposing surfaces of the core layer; and
a conductive pattern formed in multiple layers on the core layer and the build-up layers,
wherein the first resin layer forms an electronic component mounting surface of which an electronic component mounting pad on which an electronic component is mounted is exposed, the second resin layer forms an external connection terminal contacting surface of which an external connection terminal pad is exposed, and a volume of the first resin layer is greater than a volume of the second resin layer.

11. The printed circuit board of claim 10, further comprising a trench disposed on the first surface of the glass core and filled by the first resin layer.

12. The printed circuit board of claim 10, further comprising a groove formed on the first surface of the glass core and filled by the first resin layer.

13. The printed circuit board of claim 10, wherein a coefficient of thermal expansion of the electronic component mounting surface is greater than a coefficient of thermal expansion of the external connection terminal contacting surface with respect on a thickness direction.

14. The printed circuit board of claim 10, wherein the resin layer comprises a reinforcing agent.

15. The printed circuit board of claim 10, further comprising:
a through-hole passing through the core layer; and
a resin protecting unit disposed between the glass core and the through hole.

16. The printed circuit board of claim 15, wherein the through-hole comprises an hourglass shape.
